(19) United States
(12) Patent Application Publication
(10) Pub. No.: US 2014/0048319 A1
(43) Pub. Date: Feb. 20, 2014

(54) WIRING BOARD WITH HYBRID CORE AND DUAL BUILD-UP CIRCUITRIES

(71) Applicant: Bridge Semiconductor Corporation, Taipei City (TW)

(72) Inventors: Wei-Kuang PAN, Taipei City (TW); Charles W.C. LIN, Singapore (SG); Chia-Chung WANG, Hsinchu (TW)

(73) Assignee: Bridge Semiconductor Corporation, Taipei City (TW)

(21) Appl. No.: 13/963,001

(22) Filed: Aug. 9, 2013

Related U.S. Application Data
(63) Continuation-in-part of application No. 13/788,144, filed on Mar. 7, 2013.
Application No. 13/788,144 is a continuation-in-part of application No. 13/615,819, filed on Sep. 14, 2012.
Application No. 13/615,819 is a continuation-in-part of application No. 13/733,226, filed on Jan. 3, 2013.
Application No. 13/733,226 is a continuation-in-part of application No. 13/738,314, filed on Jan. 10, 2013.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.

(51) Int. Cl. H05K 1/02

(52) U.S. Cl. CPC H05K 1/0216
USPC 174/258; 174/266

(57) ABSTRACT

A wiring board with built-in metal slugs includes a dielectric hybrid core and build-up circuitries. The metal slugs extend into apertures of a stiffener of the hybrid core and are electrically connected to the build-up circuitry. The build-up circuitry covers the metal slugs and the stiffener and provides signal routing. The metal slugs can serve as power and ground planes for the wiring board.

### CROSS REFERENCE TO RELATED APPLICATION

This application is a continuation-in-part of U.S. application Ser. No. 13/788,144, entitled “THERMALLY ENHANCED WIRING BOARD WITH BUILT-IN HEAT SINK AND BUILD-UP CIRCUITRY” filed Mar. 7, 2013.

U.S. application Ser. No. 13/788,144 filed Mar. 7, 2013 is a continuation-in-part of U.S. application Ser. No. 13/615,819 filed Sep. 14, 2012, a continuation-in-part of U.S. application Ser. No. 13/733,226 filed Jan. 3, 2013 and a continuation-in-part of U.S. application Ser. No. 13/738,314 filed Jan. 10, 2013.

U.S. application Ser. No. 13/615,819 filed Sep. 14, 2012, U.S. application Ser. No. 13/733,226 filed Jan. 3, 2013 and U.S. application Ser. No. 13/738,314 filed Jan. 10, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a wiring board with a metal/dielectric hybrid core, and more particularly to a wiring board having a plurality of metal slugs implanted in the hybrid core for power and ground connections.

2. Description of Related Art

Power distribution in wiring boards has always been a concern for systems such as processors and FPGA that require the handling of very high currents on power supply connections. To alleviate the voltage drop problem and also provide electromagnetic shielding, processing systems and subsystems integrated on an interconnect substrate typically require specific layers to carry the power supply and returns (e.g., power and ground planes). This is due to a large metal plate that dedicated to power supply distribution can reduce the voltage drop significantly. Moreover, low voltage drop is also advantageous to low power device where signal integrity can be maintained and improper malfunction of the device can be avoided. However, due to layout estate limitations, most build-up substrate's power and ground planes are designed with scattered metal pads mingled in the circuitry layers and connected through small plated through-holes in the core. As a result, the effective resistance of the power delivery would be high and inevitably suffers significant voltage drop in the circuitry. Furthermore, mixing power and ground planes with signal traces in the build-up layers can induce large amount of noise and degrade signal integrity.

U.S. Pat. No. 6,711,812 to Lu et al., U.S. Pat. No. 6,528,882 to Ding et al., U.S. Pat. No. 6,323,439 to Kambe et al., U.S. Pat. No. 8,058,561 to Chen et al., and U.S. Pat. No. 8,061,025 to Cho et al. disclose a thermally enhanced wiring board or substrate in which one or more dielectric layers and conductive layers are laminated at both sides of a metal sheet. This metal core structure allows heat flows through the metal plate to the bottom surface of the substrate and then to ambient environment or next level assembly. As metal core is electrically conductive, it blocks the electrical connection between the top and bottom circuitries. As such, a plurality of plated-through-holes is created in the resin-filled metal holes to provide electrical connection for the top and bottom sides of the circuitries. Forming through-holes in a metal hole requires double drillings and resin filling which is tedious and may result in yield loss. Furthermore, as the metal core is a single electrically continuous sheet, it can't be used for power distribution if there is no other metal plate properly designed for its return.

Despite numerous wiring boards or substrates using a metal core reported in the literature, the voltage drop issue has not been adequately resolved. It is therefore desirable to provide a wiring board which can minimize the voltage drop and maintain signal integrity.

### SUMMARY OF THE INVENTION

The present invention has been developed in view of such a situation, and an object thereof is to provide a wiring board with a plurality of built-in metal slugs in the hybrid core which can effectively shorten the power delivery and ground return paths and therefore reduce resistance and parasitic capacitance. Further, the metal slugs for the use of power and ground planes can be connected by conductive micro-vias and thus minimize the voltage drop caused by plated through holes. Accordingly, the present invention provides a wiring board that includes a hybrid core having a stiffener and plural metal slugs, a first build-up circuitry, a second build-up circuitry, and a plated through hole for electrical connection of the first and the second build-up circuitries.

In a preferred embodiment, the metal slugs extend into plural apertures of the stiffener and are coplanar with the stiffener in the first and second vertical directions. The metal slugs can be copper or aluminum slugs, and preferably has a thickness range between 25 microns and 2 mm, more preferably between 100 microns and 1 mm, and most preferably between 200 microns and 500 microns. The metal slugs in the hybrid core serve as ground and power planes. For instance, the metal slugs can include one or more power planes and one or more ground planes, and the total volume of the power planes can be equal to the total volume of the ground planes. The multiple metal slugs built-in the hybrid core allow a flexible design by adjusting numbers of power and ground planes, their thickness, shapes and locations. Accordingly, equalizing the terminal currents for power delivery and return becomes feasible.

The stiffener can extend to peripheral edges of the wiring board and can be a single or multi-layer structure with embedded single-level conductive traces or multi-level conductive traces, such as multi-layer circuit board. The stiffener can be made of organic materials such as resin laminate or copper-clad laminate. The stiffener can be made of ceramics or other various inorganic materials, such as aluminum oxide (Al₂O₃), aluminum nitride (AlN), silicon nitride (SiN), silicon (Si), glass, etc. In addition, the apertures of the stiffener can be in close proximity to and be laterally aligned with peripheral edges of the metal slugs in the lateral direction to prevent the metal slugs from undesirable movement. For instance, a gap in between the metal slug and the aperture of the stiffener can be in a range of about 0.001 to 1 mm.

The first build-up circuitry covers the hybrid core in the first vertical direction, while the second build-up circuitry covers the hybrid core in the second vertical direction. The first build-up circuitry can include a first dielectric layer, first via openings and one or more first conductive traces, while the second build-up circuitry can include a second dielectric layer, second via openings and one or more second conductive traces. For instance, the first dielectric layer covers the metal slugs and the stiffener in the first vertical direction and can extend to peripheral edges of the wiring board, and the first conductive traces extend from the first dielectric layer in the first vertical direction. Likewise, second dielectric layer can cover the metal slugs and the stiffener in the second vertical direction and extend to peripheral edges of the wiring board, and the second conductive traces extend from the second dielectric layer in the second vertical direction. Accordingly, the metal slugs and the stiffener can be sandwiched between the first dielectric layer and the second dielectric layer. Moreover, the first dielectric layer and/or the second dielectric layer can extend into gaps between the stiffener and the metal slugs.

The first via openings in the first dielectric layer and the second via openings in the second dielectric layer are aligned with the metal slugs. One or more first conductive traces extend from the first dielectric layer in the first vertical direction, extend laterally on the first dielectric layer, and extend through the first via openings in the second vertical direction to provide electrical connection for the metal slugs. Likewise, one or more second conductive traces extend from the second dielectric layer in the second vertical direction, extend laterally on the second dielectric layer, and extend through the second via openings in the first vertical direction to provide electrical connection for the metal slugs. Specifically, the first and second conductive traces can directly contact the metal slugs, and thus the power delivery and return pathways can be devoid of plated through holes. The first and second build-up circuitries can include additional layers of dielectric, additional layers of via openings, and additional layers of conductive traces if needed for further signal routing.

The outmost conductive traces of the first and second build-up circuitries can respectively include one or more first and second terminal pads to provide electrical contacts for an electronic device such as a semiconductor chip, a plastic package or another semiconductor assembly. The first terminal pads can include an exposed contact surface that faces in the first vertical direction, while the second terminal pads can include an exposed contact surface that faces in the second vertical direction. As a result, the wiring board can include electrical contacts (i.e. the first and second terminal pads) that are electrically connected to one another and located on opposite surfaces that face in opposite vertical directions, so that the wiring board is stackable and electronic devices can be electrically connected to the wiring board using a wide variety of connection media including wire bonding or solder bumps as the electrical contacts.

The plated through hole can provide signal routing in the vertical direction between the first build-up circuitry and the second build-up circuitry. For instance, the plated though hole at a first end can extend to and be electrically connected to an outer or inner conductive layer of the first build-up circuitry and at a second end can extend to and be electrically connected to an outer or inner conductive layer of the second build-up circuitry. Alternatively, the plated through hole at the first end can extend to and be electrically connected to a first wiring patterned layer on a first surface of the stiffener that is electrically connected to the first build-up circuitry at a first conductive trace in a first via opening. Likewise, the plated through hole at the second end can extend to and be electrically connected to a second wiring patterned layer on a second surface of the stiffener that is electrically connected to the second build-up circuitry at a second conductive trace in a second via opening. In any case, the plated through hole extends vertically through the stiffener of the hybrid core and provides an electrical connection between the first build-up circuitry and the second build-up circuitry.

The wiring board of the present invention can further include an adhesive. The metal slugs or/and the stiffener can be affixed and mechanically connected to the first build-up circuitry using the adhesive. Thus, the adhesive can contact the metal slugs and the stiffener and is sandwiched between the metal slugs and the first build-up circuitry and between the stiffener and the first build-up circuitry.

The wiring board of the present invention can further include stoppers. The stoppers can serve as a placement guide for the metal slugs and be in close proximity to and laterally aligned with the metal slugs and laterally extend within peripheral edges of the apertures of the stiffener in lateral directions. The stoppers for the metal slugs can be made of a metal, a photosensitive plastic material or non-photosensitive material, such as copper, aluminum, nickel, iron, tin, alloys, epoxy or polyimide.

The stoppers can contact and extend from the first dielectric layer in the second vertical direction and has patterns against undesirable movement of the metal slugs. For instance, the stopper can include a continuous or discontinuous strip or an array of posts. Specifically, the stopper can be laterally aligned with four lateral surfaces of the metal slug to stop the lateral displacement of the metal slug. For instance, the stopper can be aligned along and conform to four sides, two diagonal corners or four corners of the metal slug and a gap in between the metal slug and the stopper preferably is in a range of about 0.001 to 1 mm. The metal slug can be spaced from the inner wall of the aperture by the stopper, and a bonding material can be added between the metal slug and the stiffener to enhance rigidity. Moreover, the stoppers can also be in close proximity to and laterally aligned with the inner walls of the apertures to stop the lateral displacement of the stiffener. The stoppers preferably have a thickness in a range of 10-200 microns.

The present invention can provide a semiconductor assembly in which a semiconductor device such as chip can be electrically connected to the first or second build-up circuitry using a wide variety of connection media including solder bumps, gold wires. Through the build-up circuitry, the ground/power contact pads of the semiconductor device can be electrically connected to the ground/power metal slugs built-in the hybrid core of the wiring board.

The present invention has numerous advantages. The multiple built-in metal slugs in the hybrid core can serve as ground and power planes to effectively shorten the power delivery and ground return paths and therefore reduce resistance and parasitic capacitance. The conductive vias in the build-up circuitry can provide electrical connection for the metal slugs, and thus the power delivery and return pathway can be provided by conductive vias and metal slugs so as to avoid significant voltage drop caused by plated through holes. The signal routing can be provided by the dual build-up circuitries and plated through holes and is advantageous for high I/O and high performance applications due to the high routing capability of the build-up circuitries. Further, the placement location of the metal slugs can be accurately confined by the apertures of the stiffener or the stoppers to avoid the electrical connection failure between the metal slugs and the build-up circuitry resulted from the lateral displacement of the metal slugs, thereby improving the manufacturing yield greatly. The wiring board and the semiconductor assembly using the same are reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-8 are cross-section views showing a method of making a wiring board that includes a hybrid core, a stiffener, dual build-up circuitries and plated through holes in accordance with an embodiment of the present invention, in which FIGS. 2A and 3A are top views corresponding to FIGS. 2 and 3, respectively;

FIG. 9 is a cross-sectional view showing a semiconductor assembly that includes a semiconductor device attached to the build-up circuitry of the wiring board in accordance with an embodiment of the present invention;

FIGS. 10-13 are cross-section views showing another method of making a wiring board that includes a hybrid core, a stiffener, dual build-up circuitries and plated through holes in accordance with another embodiment of the present invention; and

FIGS. 14-20 are cross-sectional views showing yet another method of making a wiring board that includes a hybrid core, stoppers, an adhesive, dual build-up circuitries and plated through holes in accordance with yet another embodiment of the present invention, in which FIGS. 15A, 15A′ and 16A are top views corresponding to FIGS. 15, 15′ and 16, respectively, and FIGS. 15B-15E are top views of other various stopper patterns for reference.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

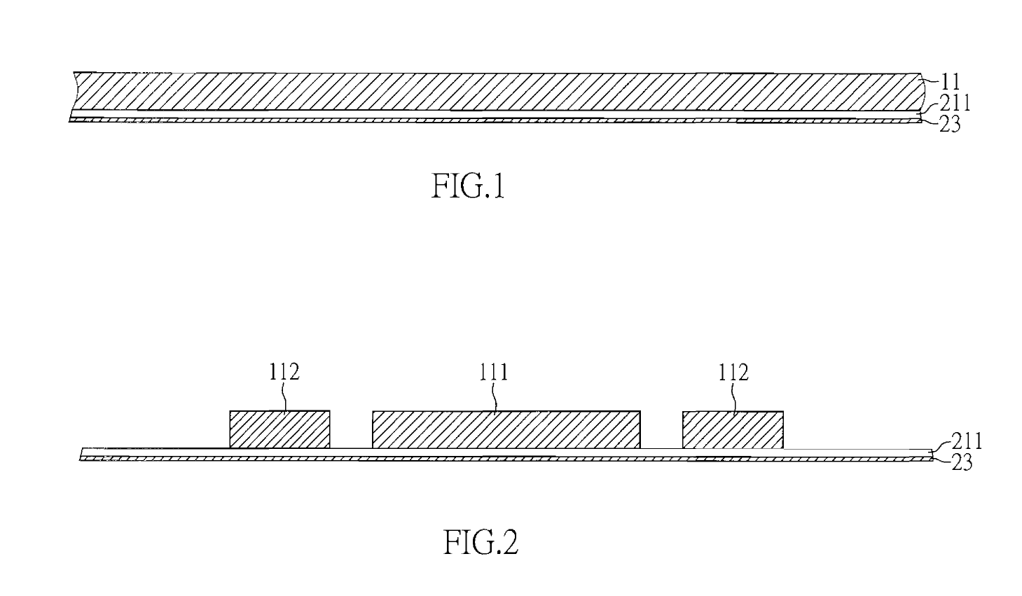

FIGS. 1-8 are cross-section views showing a method of making a wiring board that includes multiple metal slugs, a stiffener, a first build-up circuitry, a second build-up circuitry and plated through holes in accordance with an embodiment of the present invention.

As shown in FIG. 8, wiring board 100 includes hybrid core 101, first build-up circuitry 201, second build-up circuitry 202 and plated through holes 411. Hybrid core 101 includes ground/power metal slugs 111, 112 and stiffener 31. First and second build-up circuitries 201, 202 cover hybrid core 101 in the upward and downward directions, respectively, and are electrically connected to ground/power metal slugs 111, 112 through first and second conductive vias 233, 243 so as to provide power delivery and return paths. Plated through holes 411 extend through stiffener 31 of hybrid core 101 and can provide signal transduction pathway between first and second build-up circuitries 201, 202.

FIG. 1 is a cross-sectional view of a laminate substrate that includes metal sheet 11, first dielectric layer 211 and first metal layer 23. Metal sheet 11 covers first dielectric layer 211 in the upward direction and is illustrated as a copper sheet with a thickness of 200 microns. First metal layer 23 covers first dielectric layer 211 in the downward direction and is illustrated as a copper layer with a thickness of 17 microns. First dielectric layer 211, such as epoxy resin, glass-epoxy, polyimide and the like, is sandwiched between metal sheet 11 and first metal layer 23 and typically has a thickness of 50 microns.

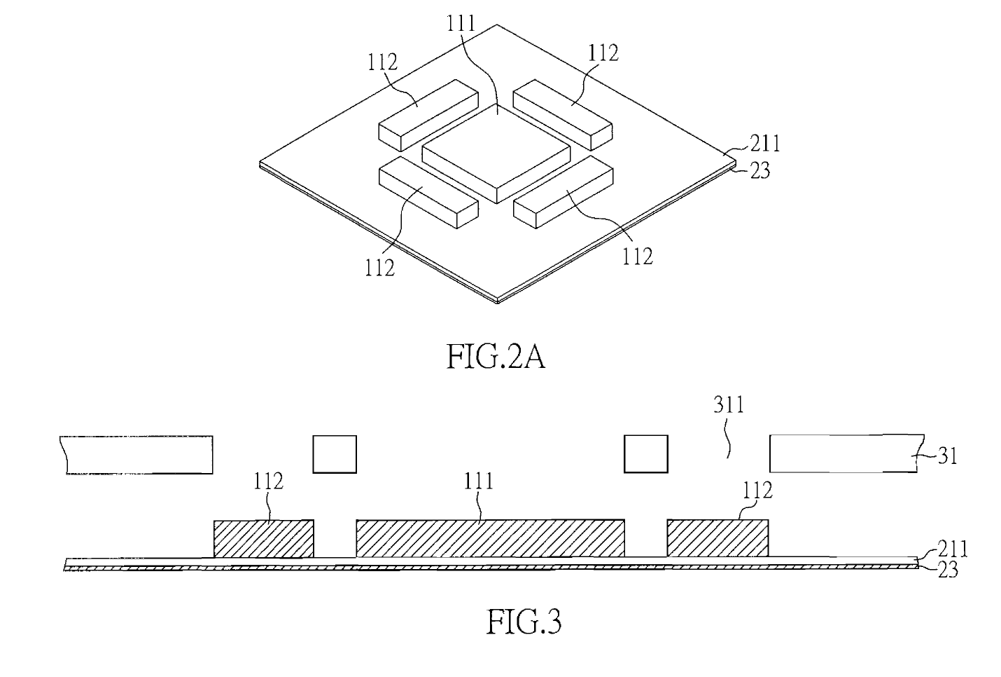

FIGS. 2 and 2A are cross-sectional and top views, respectively, of the structure with ground metal slug 111 and power metal slugs 112 defined on first dielectric layer 211. Selected portions of metal sheet 11 can be removed using photolithography and wet etching to define the remaining portions of metal sheet 11 as ground metal slug 111 and power metal slugs 112. In this illustration, the total volume of power metal slugs 112 is equal to that of ground metal slug 111 so as to equalize the terminal currents for power delivery and return and minimize voltage drop.

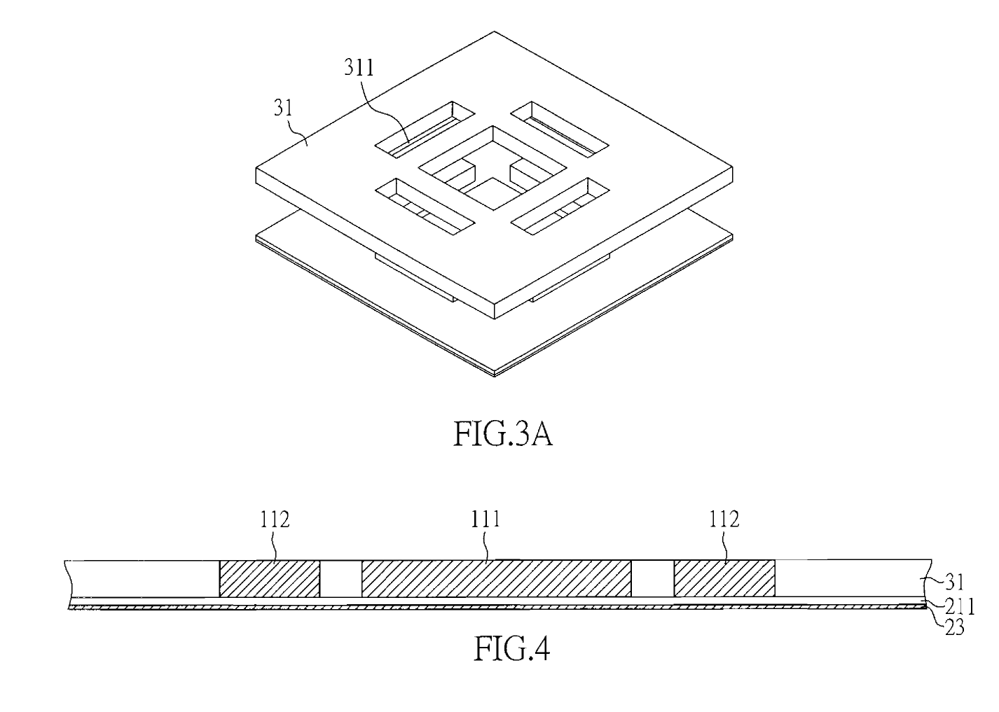

FIGS. 3 and 4 are cross-sectional views showing a process of laminating stiffener 31 onto first dielectric layer 211, and FIG. 3A is a top view corresponding to FIG. 3. The lamination process is executed by inserting ground/power metal slugs 111, 112 into apertures 311 of stiffener 31. Ground metal slug 111 and power metal slugs 112 are spaced from one another by stiffener 31 and coplanar with stiffener 31 in the upward and downward directions. In this embodiment, stiffener 31 is illustrated as a resin laminate with a thickness of about 200 microns. Apertures 311 are formed by laser cutting through stiffener 31 and can be formed with other techniques such as punching and mechanical drilling.

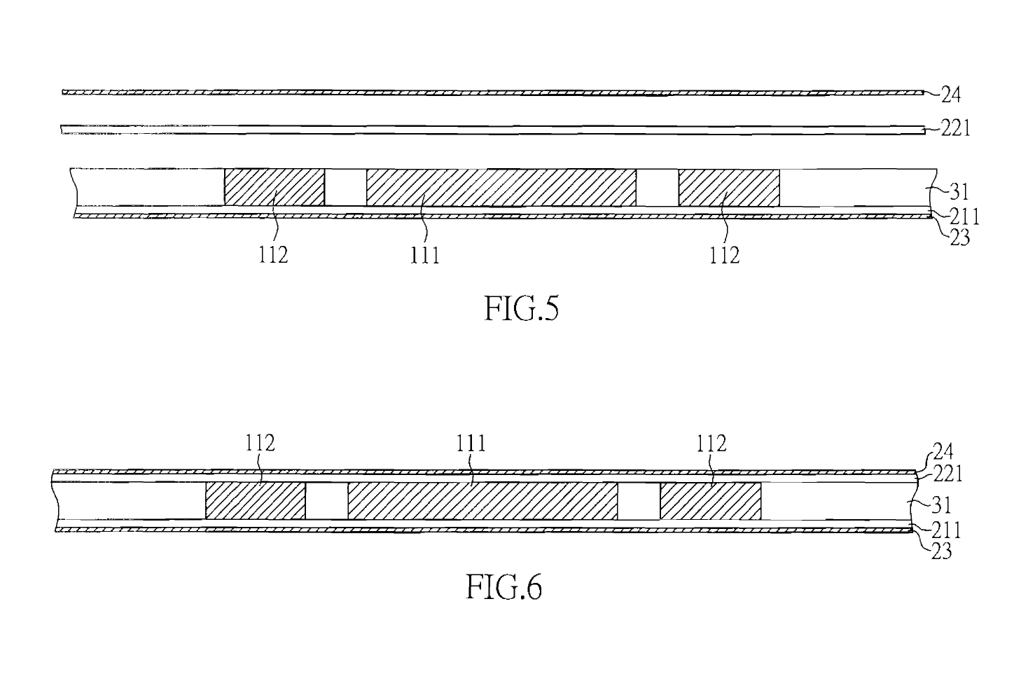

FIGS. 5 and 6 are cross-sectional views showing a process of laminating second dielectric layer 221 and second metal layer 24 onto ground/power metal slugs 111, 112 and stiffener 31 in the upward direction. Second dielectric layer 221 is sandwiched between second metal layer 24 and ground/power metal slugs 111, 112, and between second metal layer 24 and stiffener 31. Second dielectric layer 221 can be epoxy resin, glass-epoxy, polyimide and the like and typically has a thickness of 50 microns. Preferably, first dielectric layer 211 and second dielectric layer 221 are the same material. Second metal layer 24 is illustrated as a copper layer with a thickness of 17 microns. Under pressure and heat, second dielectric layer 221 is melt and compressed by applying downward pressure to second metal layer 24 or/and upward pressure to first metal layer 23. After second dielectric layer 221 and second metal layer 24 are laminated onto stiffener 31 and ground/power metal slugs 111, 112, second dielectric layer 221 is solidified. Accordingly, as shown in FIG. 6, second dielectric layer 221 as solidified provides secure robust mechanical bonds between second metal layer 24 and ground/power metal slugs 111, 112, and between second metal layer 24 and stiffener 31.

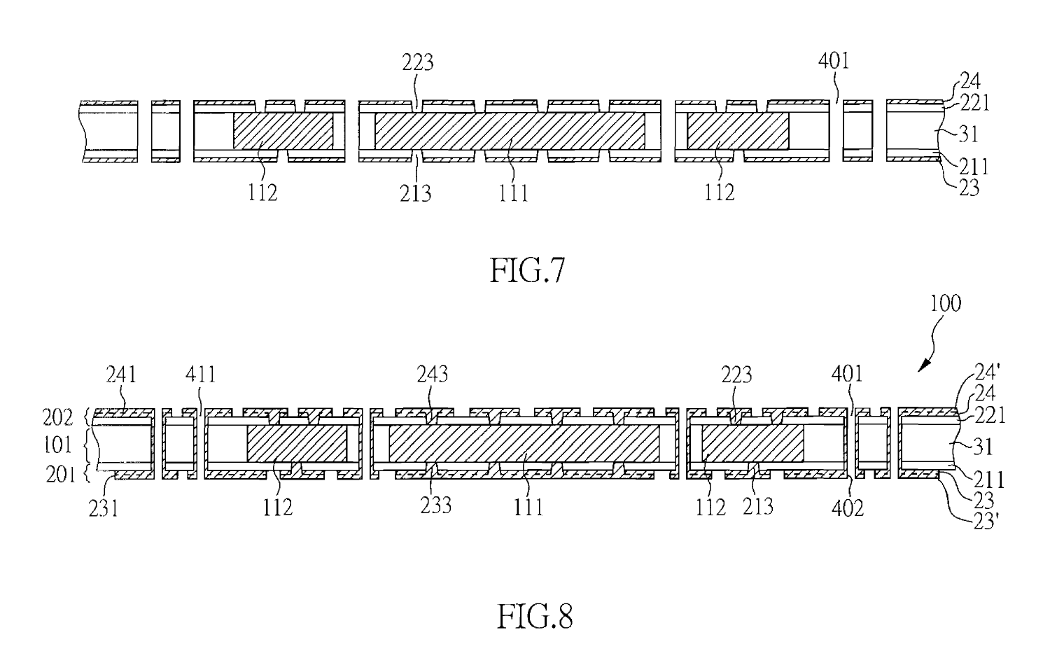

FIG. 7 is a cross-sectional view of the structure provided with first via openings 213, second via openings 223 and through holes 401. First via openings 213 extend through first metal layer 23 and first dielectric layer 211 to expose selected portions of ground/power metal slugs 111, 112 in the downward direction. Second via openings 223 extend through second metal layer 24 and second dielectric layer 221 to expose selected portions of ground/power metal slugs 111, 112 in the upward direction. Through holes 401 extend through first metal layer 23, first dielectric layer 211, stiffener 31, second dielectric layer 221 and second metal layer 24 in the vertical direction. First via openings 213 and second via openings 223 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser. Through holes 401 are formed by mechanical drilling and can be formed by other techniques such as laser drilling and plasma etching with or without wet etching.

Referring now to FIG. 8, first conductive traces 231 are formed on first dielectric layer 211 by depositing first plated layer 23′ on first metal layer 23 and into first via openings 213 and then patterning first metal layer 23 and first plated layer 23′ thereon. Alternatively, in some embodiments which apply a laminate substrate without first metal layer 23, the first dielectric layer 211 can be directly metallized to form first conductive traces 231. Meanwhile, second conductive traces 241 are formed on second dielectric layer 221 by depositing second plated layer 24′ on second metal layer 24 and into second via openings 223 and then patterning second metal layer 24 and second plated layer 24′ thereon. Likewise, second dielectric layer 221 also can be directly metallized to form second conductive traces 241 when no second metal layer 24 is laminated on second dielectric layer 221 in the previous process.

Also shown in FIG. 8 is connecting layer 402 deposited in through holes 401 to provide plated through holes 411. Connecting layer 402 is a hollow tube that covers the sidewall of through holes 401 in lateral directions and extends vertically to electrically connect first metal layer 23 as well as first plated layer 23′ thereon to second metal layer 24 as well as second plated layer 24′ thereon, and an insulative filler can optionally fill the remaining space in through holes 401. Alternatively, connecting layer 402 can fill through hole 401 in which case plated through hole 411 is a metal post and there is no space for an insulative filler in through holes 401.

Preferably, first plated layer 23′, second plated layer 24′ and connecting layer 402 are the same material deposited simultaneously in the same manner and have the same thickness. First plated layer 23′, second plated layer 24′ and connecting layer 402 can be deposited by numerous techniques including electroplating, electroless plating, evaporating, sputtering, and their combinations as a single layer or multiple layers. For instance, they are deposited by first dipping the structure in an activator solution to render the dielectric layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, plated layers can be patterned to form first conductive traces 231 and second conductive traces 241 by numerous techniques including wet etching, electro-chemical etching, laser-assist etching, and their combinations with an etch mask (not shown) thereon that defines first conductive traces 231 and second conductive traces 241, respectively.

First metal layer 23, second metal layer 24, first plated layer 23′, second plated layer 24′ and connecting layer 402 are shown as a single layer for convenience of illustration. The boundary (shown in phantom) between the metal layers may be difficult or impossible to detect since copper is plated on copper. However, the boundaries between first plated layer 23′ and first dielectric layer 211, between second plated layer 24′ and second dielectric layer 221, between connecting layer 402 and first dielectric layer 211, between connecting layer 402 and second dielectric layer 221, and between connecting layer 402 and stiffener 31 are clear.

Accordingly, as shown in FIG. 8, wiring board 100 is accomplished and includes hybrid core 101, dual build-up circuitries 201, 202 and plated through holes 411. In this illustration, first build-up circuitry 201 includes first dielectric layer 211 and first conductive traces 231, while second build-up circuitry 202 includes second dielectric layer 221 and second conductive traces 241. Hybrid core 101 includes ground/power metal slugs 111, 112 and stiffener 31. Ground/power metal slugs 111, 112 extend into apertures 311 of stiffener 31 and are coplanar with stiffener 31 in the upward and downward directions. First conductive traces 231 extend from first dielectric layer 211 in the downward direction, extend laterally on first dielectric layer 211 and extend into first via openings 213 in the upward direction to form first conductive vias 233 in direct contact with ground/power metal slugs 111, 112. Likewise, second conductive traces 241 extend from second dielectric layer 221 in the upward direction, extend laterally on second dielectric layer 221 and extend into second via openings 223 in the downward direction to form second conductive vias 243 in direct contact with ground/power metal slugs 111, 112. As a result, the power delivery and ground return paths of wiring board 100 are provided by ground/power metal slugs 111, 112 and first and second conductive vias 233, 243. Plated through holes 411 are essentially shared by hybrid core 101 and dual build-up circuitries 201, 202, and extend through stiffener 31, first dielectric layer 211 and second dielectric layer 221 in the vertical directions to provide electrical connection between first conductive traces 231 and second conductive traces 241.

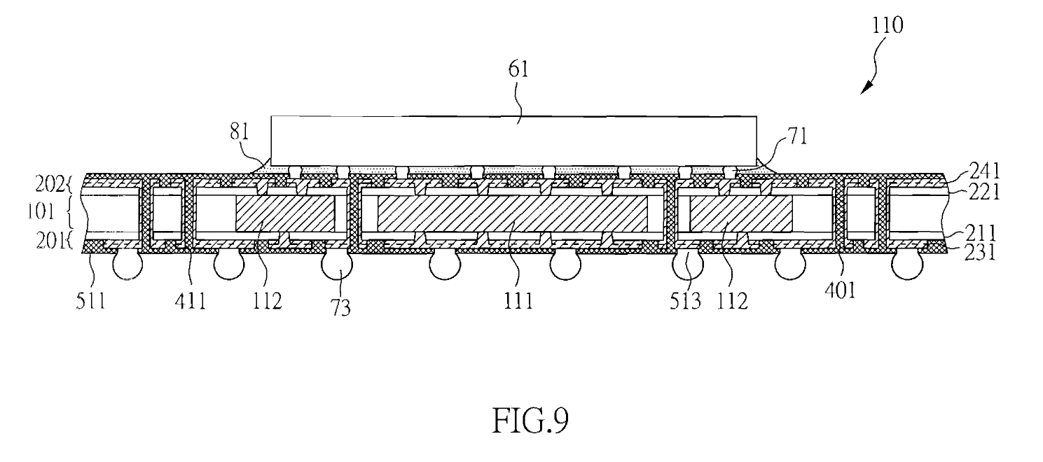

FIG. 9 is a cross-sectional view of a semiconductor assembly 110 in which semiconductor device 61 is electrically connected to second build-up circuitry 202 via solder bumps 71 on selected portions of second conductive traces 241. The signal contact pads of semiconductor device 61 are electrically connected to the signal transduction pathways of the wiring board that are provided by patterned wiring layers of first and second build-up circuitries 201, 202 and plated through holes 411. The ground/power contact pads of semiconductor device 61 are electrically connected to the power delivery and return pathways of the wiring board that are provided by conductive vias of first and second build-up circuitries 201, 202 and ground/power metal slugs 111, 112. Also shown in FIG. 9 are solder mask material 511 over first and second build-up circuitries 201, 202 and underfill 81 dispensed between semiconductor device 61 and solder mask material 511. In this illustration, solder mask material 511 further fills the remaining space of plated through holes 411. Selected portions of first conductive traces 34 and second conductive traces 234 are exposed from solder mask openings 513 to accommodate solder bumps 71 and solder balls 73. Through solder balls 73 on selected portions of first conductive traces 231, semiconductor assembly 110 can be further electrically connected with another assembly or external components.

### Embodiment 2

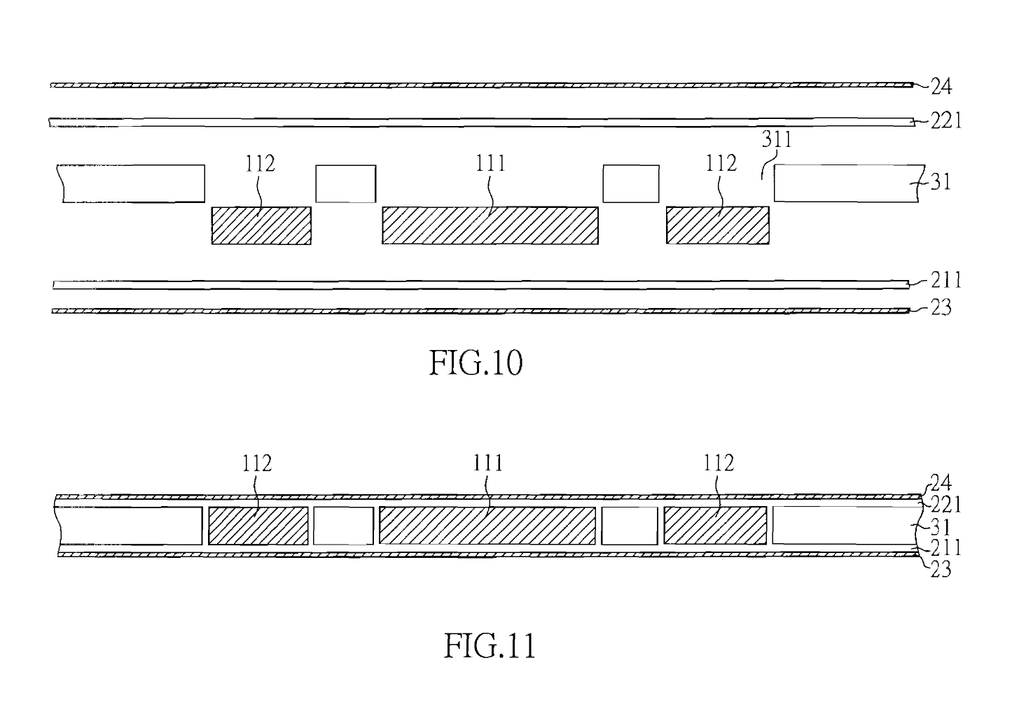

FIGS. 10-13 are cross-section views showing another method of making a wiring board that includes multiple metal slugs, a stiffener, a first build-up circuitry, a second build-up circuitry and plated through holes in accordance with another embodiment of the present invention.

For purposes of brevity, any description in Embodiment 1 is incorporated herein insofar as the same is applicable, and the same description need not be repeated.

FIGS. 10 and 11 are cross-sectional views showing a process of laminating ground metal slug 111, power metal slugs 112, stiffener 31, first dielectric layer 211, second dielectric layer 221, first metal layer 23 and second metal layer 24. In this embodiment, stiffener 31 is illustrated as a ceramic sheet with multiple apertures 311, and ground/power metal slugs 111, 112 are illustrated as multiple solid copper slugs. Ground metal slug 111, power metal slugs 112 and stiffener 31 are provided between first dielectric layer 211/first metal layer 23 and second dielectric layer 221/second metal layer 24. Under pressure and heat, ground/power metal slugs 111, 112 are inserted into apertures 311 of stiffener 31, and first dielectric layer 211 and second dielectric layer 221 between first metal layer 23 and stiffener 31/metal slugs 111, 112 and between second metal layer 24 and stiffener 31/metal slugs 111, 112 are compressed and further forced into gaps between ground/power metal slugs 111, 112 and stiffener 31. Accordingly, as shown in FIG. 11, first and second dielectric layer 211, 221 as solidified provides secure robust mechanical bonds between first metal layer 23 and ground/power metal slugs 111, 112, between first metal layer 23 and stiffener 31, between second metal layer 24 and ground/power metal slugs 111, 112, between second metal layer 24 and stiffener 31, and between stiffener 31 and ground/power metal slugs 111, 112. In this illustration, each aperture 311 of stiffener 31 has a dimension of about the same to that of corresponding ground/power metal slugs 111, 112.

Accordingly, apertures 311 of stiffener 31 are in close proximity to and laterally aligned with peripheral edges of ground/power metal slugs 111, 112 in the lateral direction, and thus can prevent ground/power metal slugs 111, 112 from undesirable movement and ensure predetermined portions of ground/power metal slugs 111, 112 being aligned with laser. Preferably, a gap in between ground/power metal slugs 111, 112 and aperture 311 is in a range of about 0.001 to 1 mm. However, since ground/power metal slugs 111, 112 have large connection surface, the lateral movement of ground/power metal slugs 111, 112 would not result in the electrical connection failure between build-up circuitries and ground/power metal slugs 111, 112. Thereby, it is not indispensable to prevent lateral displacement of ground/power metal slugs 111, 112 for this case.

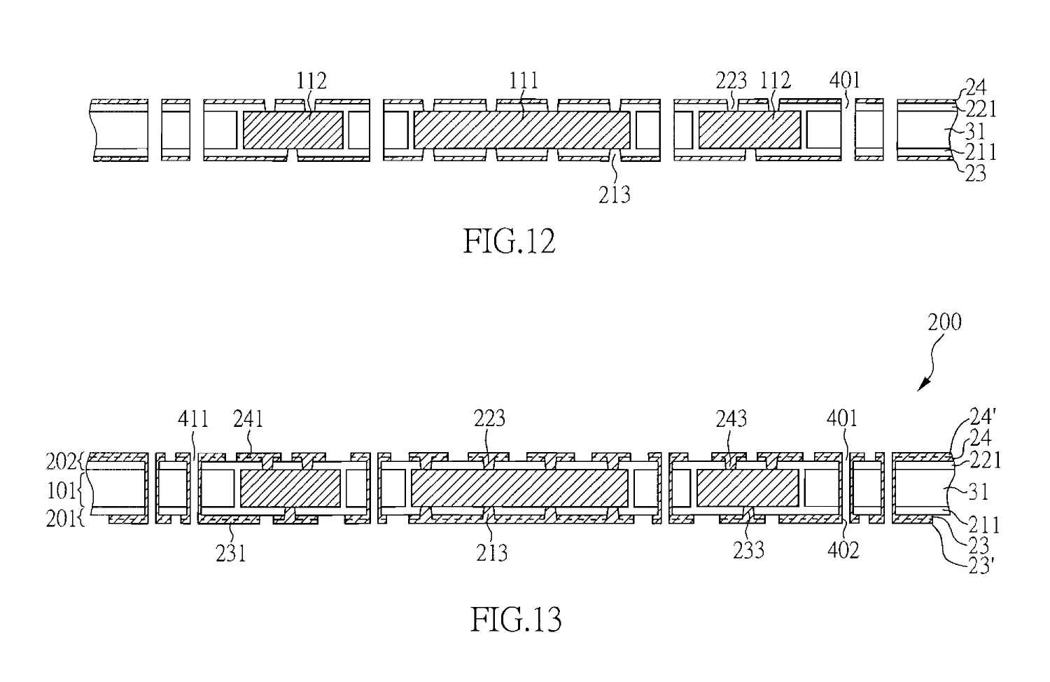

FIG. 12 is a cross-sectional view of the structure provided with first via openings 213, second via openings 223 and through holes 401. First via openings 213 extend through first metal layer 23 and first dielectric layer 211 to expose selected portions of ground/power metal slugs 111, 112 in the downward direction. Second via openings 223 extend through second metal layer 24 and second dielectric layer 221 to expose selected portions of ground/power metal slugs 111, 112 in the upward direction. Through holes 401 extend through first metal layer 23, first dielectric layer 211, stiffener 31, second dielectric layer 221 and second metal layer 24 in the vertical direction.

Referring now to FIG. 13, first conductive traces 231 are formed on first dielectric layer 211 by depositing first plated layer 23′ on first metal layer 23 and into first via openings 213 and then patterning first metal layer 23 and first plated layer 23′ thereon. Meanwhile, second conductive traces 241 are formed on second dielectric layer 221 by depositing second plated layer 24′ on second metal layer 24 and into second via openings 223 and then patterning second metal layer 24 and second plated layer 24′ thereon. Also shown in FIG. 13 are plated through holes 411 formed by depositing connecting layer 402 in through holes 401.

Accordingly, as shown in FIG. 13, wiring board 200 is accomplished and includes hybrid core 101, first build-up circuitry 201, second build-up circuitry 202 and plated through holes 411. In this illustration, first build-up circuitry 201 includes first dielectric layer 211 and first conductive traces 231, and second build-up circuitry 202 includes second dielectric layer 221 and second conductive traces 241. Hybrid core 101 includes ground/power metal slugs 111, 112 and stiffener 31 and is sandwiched between first and second build-up circuitries 201, 202. First and second conductive traces 231, 241 respectively extend into first and second via openings 213, 223 to form first and second conductive vias 233, 243 in direct contact with ground/power metal slugs 111, 112 so as to effectively shorten the power delivery and ground return paths. Plated through holes 411 extend through stiffener 31, first dielectric layer 211 and second dielectric layer 221 to provide signal transduction paths between first and second build-up circuitries 201, 202.

### Embodiment 3

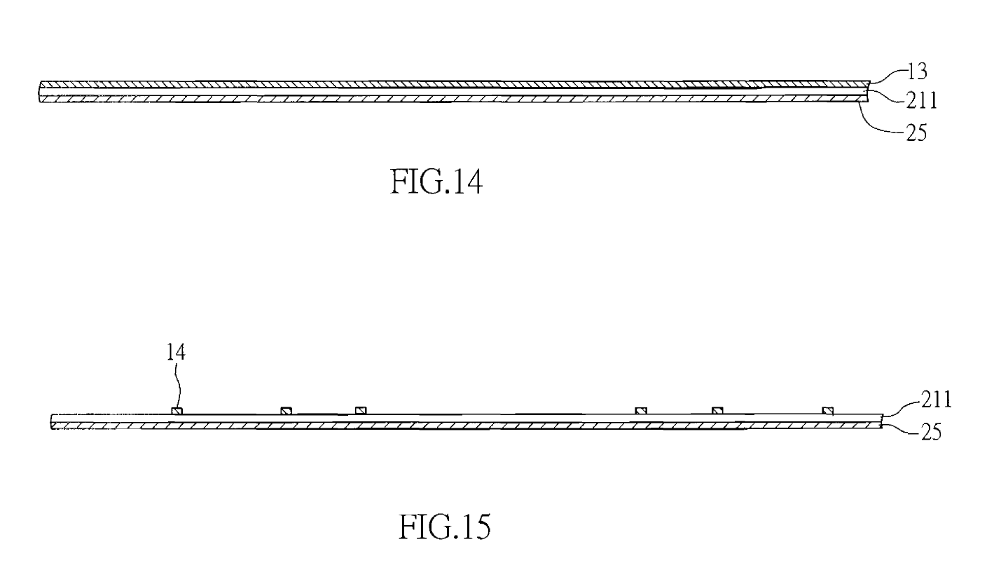

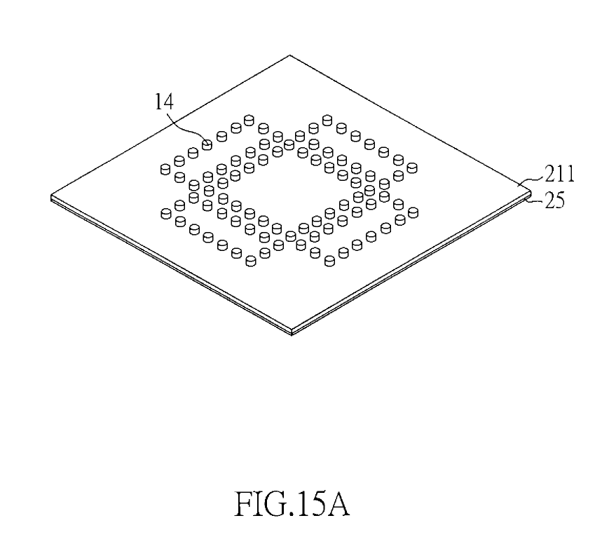

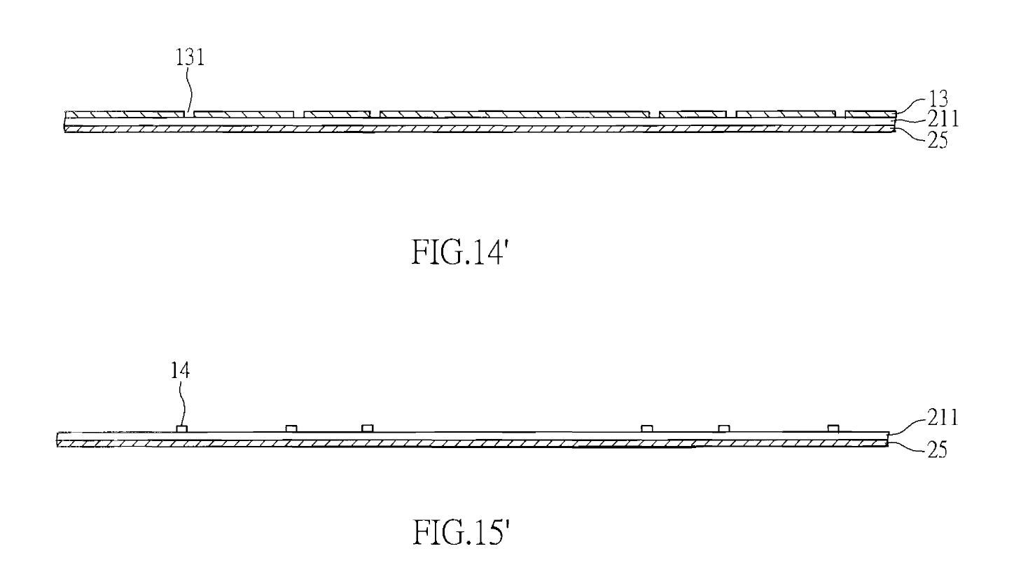

FIGS. 14-20 are cross-sectional views showing yet another method of making a wiring board that includes multiple metal slugs, stoppers, a stiffener, an adhesive, a first build-up circuitry, a second build-up circuitry and plated through holes in accordance with yet another embodiment of the present invention.

For purposes of brevity, any description in Embodiments 1 and 2 is incorporated herein insofar as the same is applicable, and the same description need not be repeated.

FIG. 14 is a cross-sectional view of a laminate substrate that includes metal layer 13, first dielectric layer 211 and support plate 25. Metal layer 13 is illustrated as a copper layer with a thickness of 35 microns. However, metal layer 13 can also be made of other various metal materials and is not limited to a copper layer. Besides, metal layer 13 can be deposited on first dielectric layer 211 by numerous techniques including lamination, electroplating, electroless plating, evaporating, sputtering, and their combinations as a single layer or multiple layers, and preferably has a thickness in a range of 10 to 200 microns.

First dielectric layer 211 typically has a thickness of 50 microns. In this embodiment, first dielectric layer 211 is sandwiched between metal layer 13 and support plate 25. However, support plate 25 may be omitted in some embodiments. Support plate 25 typically is made of copper. The thickness of support plate 25 can range from 25 to 1000 microns, and preferably ranges from 35 to 100 microns in consideration of process and cost. In this embodiment, support plate 25 is illustrated as a copper plate with a thickness of 35 microns.

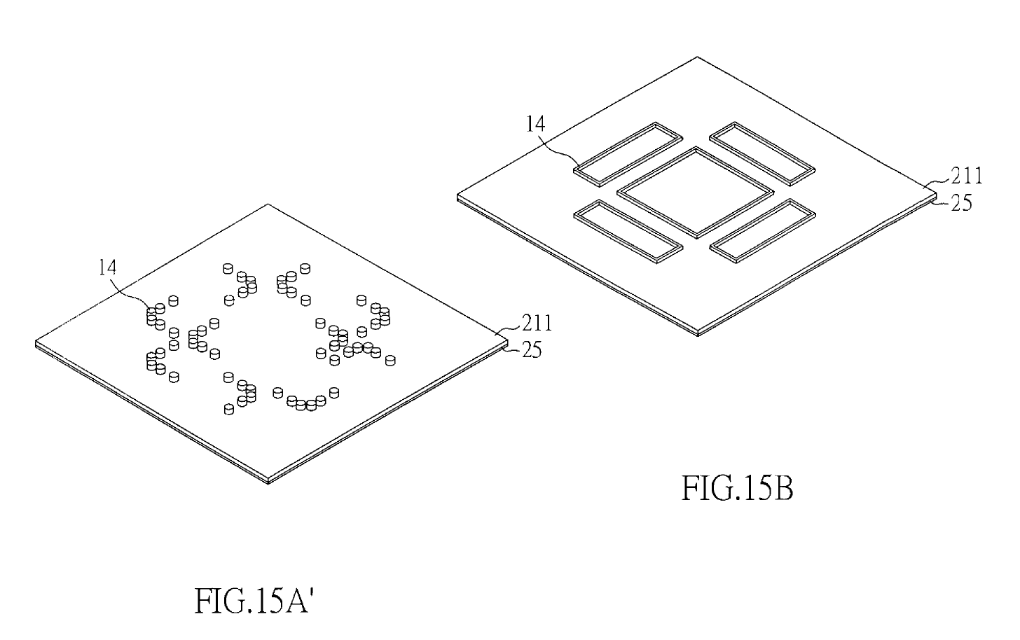

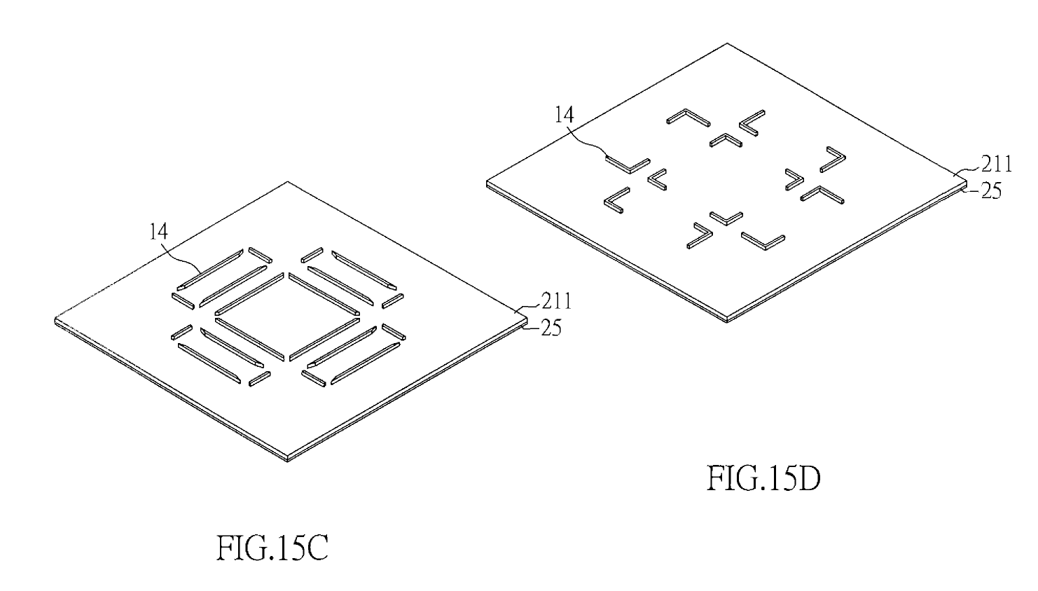

FIGS. 15 and 15A are cross-sectional and top views, respectively, of the structure with multiple stoppers 14 formed on first dielectric layer 211. Stoppers 14 can be formed by removing selected portions of metal layer 13 using photolithography and wet etching. In this illustration, each stopper 14 consists of plural metal posts in a rectangular frame array and conforms to four sides of corresponding metal slug subsequently disposed on first dielectric layer 211. However, stopper patterns are not limited thereto and can be other various patterns against undesirable movement of the subsequently disposed metal slugs.

FIGS. 14′ and 15′ are cross-sectional views showing an alternative process of forming stoppers 14 on first dielectric layer 211, and FIG. 15A′ is a top view corresponding to FIG. 15′.

FIG. 14′ is a cross-sectional view of a laminate substrate with multiple sets of cavities 131 formed in metal layer 13. The laminate substrate includes metal layer 13, first dielectric layer 211 and support plate 25 as above mentioned, and cavities 131 are formed by removing selected portions of metal layer 13.

FIGS. 15′ and 15A′ are cross-sectional and top views, respectively, of the structure with multiple stoppers 14 formed on first dielectric layer 211. Stoppers 14 can be formed by dispensing or printing a photosensitive plastic material (e.g., epoxy, polyimide, etc.) or non-photosensitive material into cavities 131, followed by removing overall metal layer 13. Herein, each stopper 14 is illustrated as an array of plural resin posts and conforms to two diagonal corners of each subsequently disposed metal slug.

FIGS. 15B-15E are top views of other various stopper patterns for reference. For instance, each stopper 13 may consist of a continuous or discontinuous strip and conform to four sides (as shown FIGS. 15B and 15C), two diagonal corners or four corners (as shown in FIGS. 15D and 15E) of each subsequently disposed metal slug.

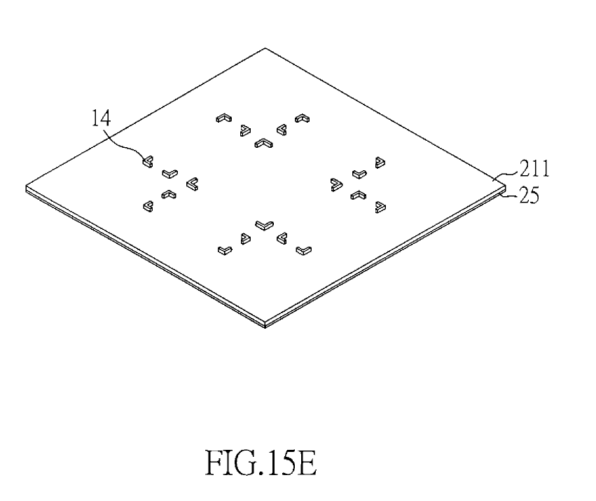

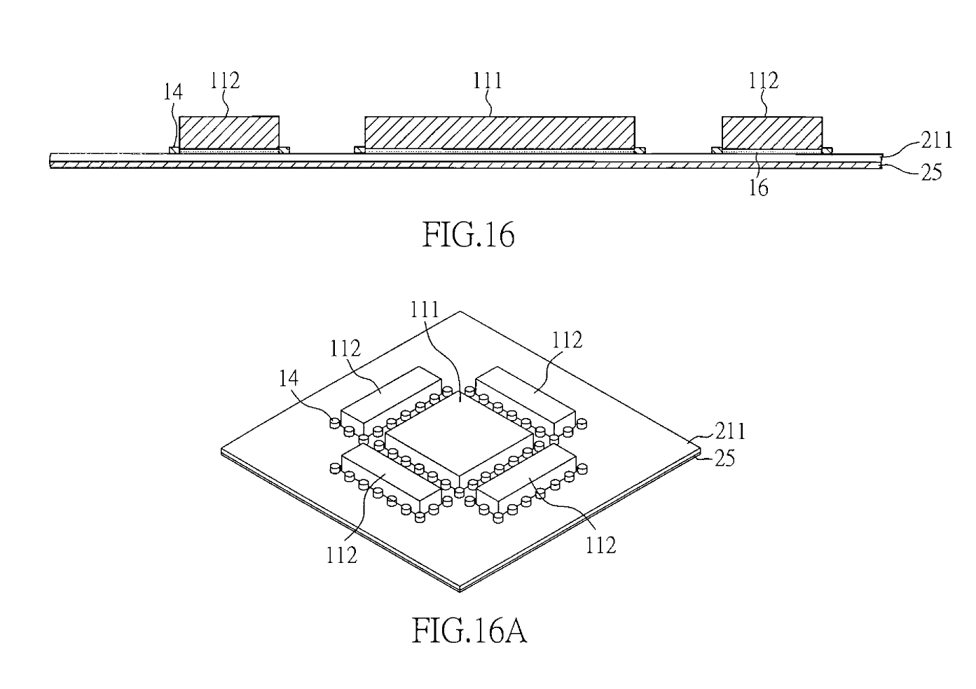

FIGS. 16 and 16A are cross-sectional and top views, respectively, of the structure with ground metal slug 111 and power metal slugs 112 mounted on first dielectric layer 211 using adhesive 16. Adhesive 16 contacts and is sandwiched between ground/power metal slugs 111, 112 and first dielectric layer 211 to provide robust mechanical bonds between ground/power metal slugs 111, 112 and first dielectric layer 211.

Stoppers 14 can serve as a placement guide for ground/power metal slugs 111, 112, and thus ground/power metal slugs 111, 112 are precisely placed at predetermined locations. Stopper 14 extend from first dielectric layer 211 beyond the attached surfaces of ground/power metal slugs 111, 112 in the upward direction and are laterally aligned with and laterally extend beyond four sides of ground/power metal slugs 111, 112 in the lateral directions. As each stopper 14 is in close proximity to and conforms to four lateral surfaces of each corresponding ground/power metal slug 111, 112 in lateral directions and adhesive 16 underneath ground/power metal slugs 111, 112 are lower than stoppers 14, any undesirable movement of ground/power metal slugs 111, 112 due to adhesive curing can be avoided. Preferably, a gap in between ground/power metal slugs 111, 112 and stopper 14 is in a range of about 0.001 to 1 mm.

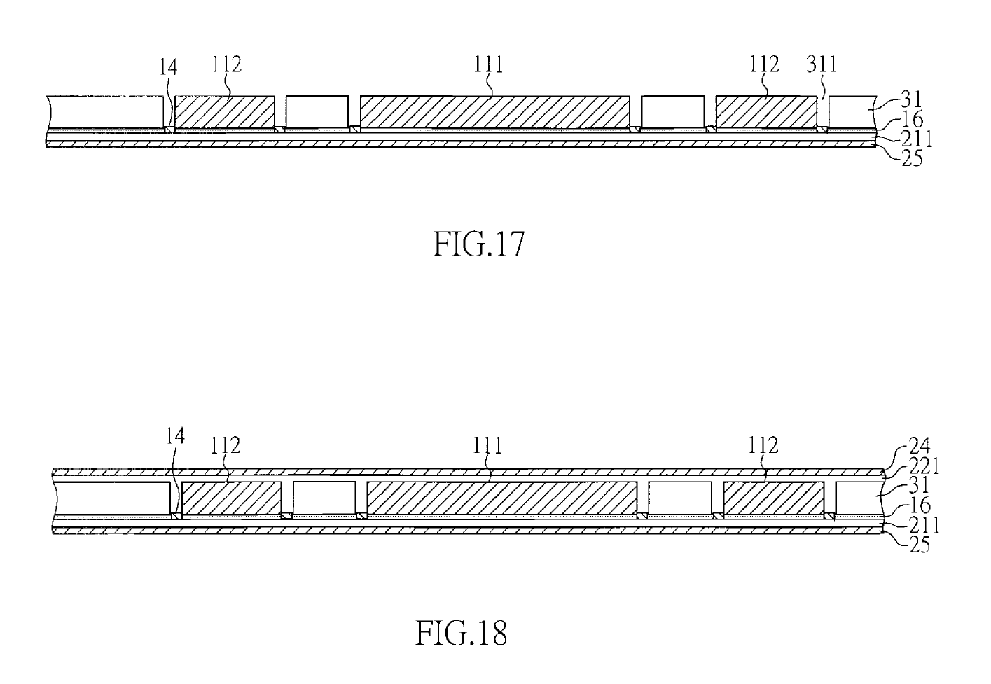

FIG. 17 is a cross-sectional view of the structure with stiffener 31 mounted on first dielectric layer 211 using adhesive 16. Ground/power metal slugs 111, 112 and stoppers 14 are aligned with and inserted into corresponding apertures 311 of stiffener 31, and adhesive 16 contact stiffener 31 and first dielectric layer 211 to provide robust mechanical bonds between stiffener 31 and first dielectric layer 211. In this embodiment, stiffener 31 is illustrated as a ceramic sheet.

Ground/power metal slugs 111, 112 and the inner wall of apertures 311 are spaced from one another by stoppers 14. In this illustration, each stopper 113 is also in close proximity to and laterally aligned with four inner walls of corresponding aperture 311 and adhesive 16 under stiffener 31 is lower than stoppers 14, and thus any undesirable movement of stiffener 31 also can be avoided before adhesive 16 is fully cured. Optionally, a bonding material (not shown in the figure) can be added between ground/power metal slugs 111, 112 and stiffener 31 to enhance rigidity.

FIG. 18 is a cross-sectional view of the structure showing second dielectric layer 221 and second metal layer 24 laminated onto ground/power metal slugs 111, 112 and stiffener 31 in the upward direction. Second dielectric layer 221 is sandwiched between second metal layer 24 and stiffener 31/metal slugs 111, 112. Under pressure and heat, second dielectric layer 221 is forced into a gap between stiffener 31 and ground/power metal slugs 111, 112. After second dielectric layer 221 and second metal layer 24 are laminated with ground/power metal slugs 111, 112 and stiffener 31, second dielectric layer 221 is solidified.

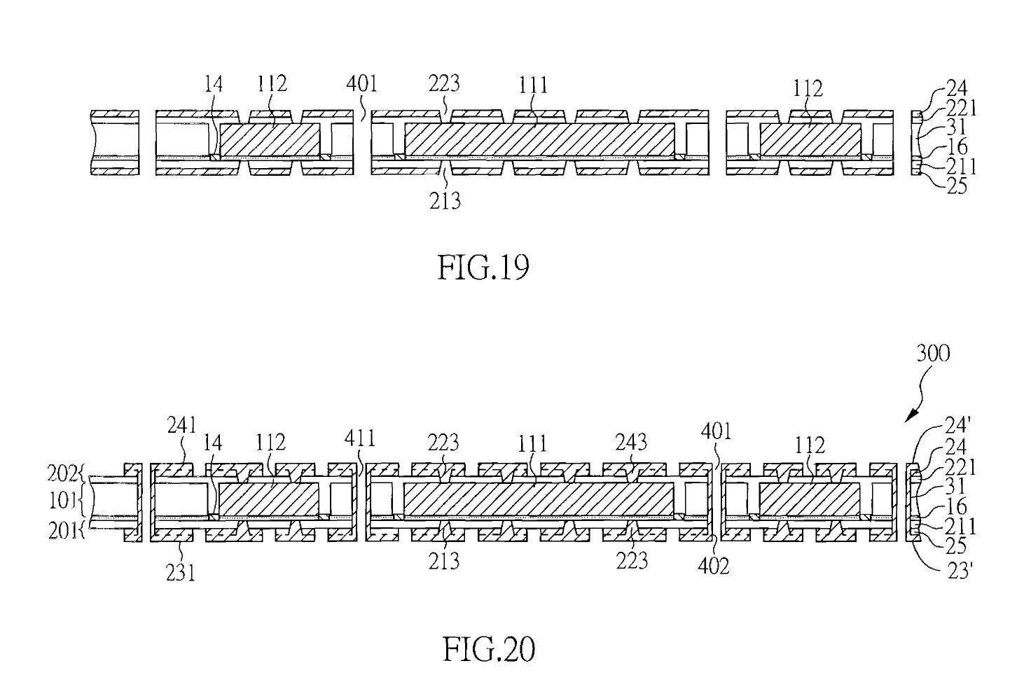

FIG. 19 is a cross-sectional view of the structure provided with first via openings 213, second via openings 223 and through holes 401. First via openings 213 extend through support plate 25, first dielectric layer 211 and adhesive 16 to expose selected portions of ground/power metal slugs 111, 112 in the downward direction. Second via openings 223 extend through second metal layer 24 and second dielectric layer 221 to expose selected portions of ground/power metal slugs 111, 112 in the upward direction. Through holes 401 extend through support plate 25, first dielectric layer 211, adhesive 16, stiffener 31, second dielectric layer 221 and second metal layer 24 in the vertical directions.

Referring now to FIG. 20, first conductive traces 231 are formed on first dielectric layer 211 by depositing first plated layer 23′ on support plate 25 and into first via openings 213 and then patterning support plate 25 and first plated layer 23′ thereon. Meanwhile, second conductive traces 241 are formed on second dielectric layer 221 by depositing second plated layer 24′ on second metal layer 24 and into second via openings 223 and then patterning second metal layer 24 and second plated layer 24′ thereon. Also shown in FIG. 20 are plated through holes 411 formed by depositing connecting layer 402 in through holes 401. Accordingly, wiring board 300 of this embodiment is accomplished and includes ground/power metal slugs 111, 112, stoppers 14, stiffener 31, adhesive 16, first build-up circuitry 201, second build-up circuitry 202 and plated through holes 411.

First conductive traces 231 extend from first dielectric layer 211 in the downward direction, extend laterally on first dielectric layer 211 and extend into first via openings 213 in the upward direction to make electrical contact with ground/power metal slugs 111, 112. Second conductive traces 241 extend from second dielectric layer 221 in the upward direction, extend laterally on second dielectric layer 221 and extend into second via openings 223 in the downward direction to make electrical contact with ground/power metal slugs 111, 112. As a result, the power delivery and return pathways of wiring board 300 is provided by ground/power metal slugs 111, 112 of hybrid core 101, first conductive vias 233 formed in first build-up circuitry 201, and second conductive vias 243 formed in second build-up circuitry 202 that both contact ground/power metal slugs 111, 112 directly. In this embodiment, ground/power metal slugs 111, 112 and stiffener 31 are affixed and mechanically connected to first build-up circuitry 201 using adhesive 16 which contacts ground/power metal slugs 111, 112, stiffener 31 and first dielectric layer 211, and is sandwiched between ground/power metal slugs 111, 112 and first build-up circuitry 201 and between stiffener 31 and first build-up circuitry 201.

The wiring boards and semiconductor assemblies described above are merely exemplary. Numerous other embodiments are contemplated. In addition, the embodiments described above can be mixed-and-matched with one another and with other embodiments depending on design and reliability considerations. The stiffener can include additional apertures to accommodate additional ground/power metal slugs and the build-up circuitries can include additional conductive traces to accommodate additional ground/power metal slugs. Likewise, additional stoppers can be further provided to accommodate additional ground/power metal slugs.

As shown in the above embodiments, a semiconductor device can share or not share the ground/power metal slugs with other semiconductor devices. For instance, a single semiconductor device can be mounted on the build-up circuitry and electrically connected to the ground/power metal slugs. Alternatively, numerous semiconductor devices can be mounted on the build-up circuitry and electrically connected to the identical ground/power metal slugs. For instance, four small chips in a 2×2 array can be attached to the build-up circuitry, and the build-up circuitry can include additional conductive vias to receive and route additional chip ground/power pads to the identical ground/power metal slugs. This may be more cost effective than providing a set of ground/power metal slugs for each chip.

The semiconductor device can be a packaged or unpackaged chip. Furthermore, the semiconductor device can be a bare chip, or a wafer level packaged die, etc. A semiconductor device can be mechanically and electrically connected to the build-up circuitry using a wide variety of connection media including gold or solder bumps, bonding wires. The stoppers can be customized for the metal slugs. For instance, the stopper can have a pattern that defines a square or rectangular area with the same or similar topography as the metal slug.

The term “adjacent” refers to elements that are integral (single-piece) or in contact (not spaced or separated from) with one another. For instance, the plated through holes are adjacent to the first and second conductive traces, but not adjacent to the metal slugs.

The term “overlap” refers to above and extending within a periphery of an underlying element. Overlap includes extending inside and outside the periphery or residing within the periphery. For instance, in the position that the first build-up circuitry faces the upward direction, the first build-up circuitry overlaps the metal slugs since an imaginary vertical line intersects the first build-up circuitry and the metal slugs, regardless of whether another element such as the adhesive is between the first build-up circuitry and the metal slugs and is intersected by the line, and regardless of whether another imaginary vertical line intersects the first build-up circuitry but not the metal slugs (beyond the apertures of the stiffener). Likewise, the first build-up circuitry overlaps the stiffener and the stiffener is overlapped by the first build-up circuitry. Moreover, overlap is synonymous with over and overlapped by is synonymous with under or beneath.

The term “contact” refers to direct contact. For instance, the plated through hole contacts the first and second conductive traces but does not contact the metal slugs.

The term “cover” refers to incomplete and complete coverage in a vertical and/or lateral direction. For instance, in the position that the first build-up circuitry faces the upward direction, the first build-up circuitry covers the metal slugs in the upward direction regardless of whether another element such as the adhesive is between the metal slugs and the first build-up circuitry, and the second build-up circuitry cover the metal slugs in the downward direction.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening”, “aperture” and “through hole” refer to a through hole and are synonymous. For instance, in the position that the first build-up circuitry faces the upward direction, the metal slugs are exposed by the stiffener in the upward direction when it is inserted into the apertures in the stiffener.

The term “inserted” refers to relative motion between elements. For instance, the metal slugs are inserted into the apertures regardless of whether the stiffener is stationary and the metal slugs move towards the stiffener, the metal slugs are stationary and the stiffener moves towards the metal slugs or the metal slugs and the stiffener both approach the other.

Furthermore, the metal slugs are inserted (or extend) into the apertures regardless of whether they go through (enter and exit) or do not go through (enter without exiting) the apertures.

The phrase “aligned with” refers to relative position between elements regardless of whether elements are spaced from or adjacent to one another or one element is inserted into and extends into the other element. For instance, the stopper is laterally aligned with the metal slug since an imaginary horizontal line intersects the stopper and the metal slug, regardless of whether another element is between the stopper and the metal slug and is intersected by the line, and regardless of whether another imaginary horizontal line intersects the metal slug but not the stopper or intersects the stopper but not the metal slug. Likewise, the first via openings are aligned with the metal slugs, and the metal slugs are aligned with the apertures.

The phrase “in close proximity to” refers to a gap between elements not being wider than the maximum acceptable limit. As known in the art, when the gap between the metal slug and the stopper or between the metal slug and the aperture of the stiffener is not narrow enough, the location error of the metal slug due to the lateral displacement of the metal slug within the gap may exceed the maximum acceptable error limit. In some cases, once the location error of the metal slug goes beyond the maximum limit, it is impossible to align the predetermined portion of the metal slug with a laser beam, resulting in the electrical connection failure between the metal slug and the build-up circuitry. According to the dimension of the predetermined portion of the metal slug, those skilled in the art can ascertain the maximum acceptable limit for a gap between the metal slug and the stopper or the aperture of the stiffener through trial and error to ensure the conductive vias being aligned with the predetermined portion of the metal slug. Thereby, the descriptions “the stoppers are in close proximity to the peripheral edges of the metal slugs” and “the apertures of the stiffener are in close proximity to the peripheral edges of the metal slugs” mean that the gap between the peripheral edges of the metal slugs and the stoppers or the apertures of the stiffener is narrow enough to prevent the location error of the metal slugs from exceeding the maximum acceptable error limit.

The phrase “mounted on” includes contact and non-contact with a single or multiple support element(s). For instance, the metal slugs are mounted on the first dielectric layer regardless of whether they contact the first dielectric layer or are separated from the first dielectric layer by an adhesive.

The phrase “electrical connection” or “electrically connects” or “electrically connected” refers to direct and indirect electrical connection. For instance, the first conductive trace provides an electrical connection between the terminal pad and the metal slugs regardless of whether the first conductive trace is adjacent to the terminal pad or electrically connected to the terminal pad by additional conductive traces of the first build-up circuitry.

The term “above” refers to upward extension and includes adjacent and non-adjacent elements as well as overlapping and non-overlapping elements. For instance, in the position that the second build-up circuitry faces the upward direction, the stopper extends above, is adjacent to and protrudes from the first dielectric layer.

The term “below” refers to downward extension and includes adjacent and non-adjacent elements as well as overlapping and non-overlapping elements. For instance, in the position that the second build-up circuitry faces the upward direction, the first build-up circuitry extends below the stiffener and the metal slugs in the downward direction regardless of whether the first build-up circuitry is adjacent to the stiffener and the metal slugs.

The “first vertical direction” and “second vertical direction” do not depend on the orientation of the wiring board, as will be readily apparent to those skilled in the art. For instance, the first build-up circuitry faces the first vertical direction and the second build-up circuitry faces the second vertical direction regardless of whether the wiring board is inverted. Likewise, the stopper is “laterally” aligned with the metal slug in a lateral plane regardless of whether the wiring board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the second build-up circuitry faces the upward direction, and the first vertical direction is the upward direction and the second vertical direction is the downward direction in the position that the second build-up circuitry faces the downward direction.

The wiring board and the semiconductor assembly using the same according to the present invention have numerous advantages. The wiring board and the semiconductor assembly are reliable, inexpensive and well-suited for high volume manufacture. The built-in metal slugs in the hybrid core can provide power delivery and return paths when interconnected with build-up circuitries. The power delivery and return pathway provided by conductive vias and metal slugs can minimize the voltage drop. The signal routing provided by the dual build-up circuitries and plated through holes is advantageous for high I/O and high performance applications due to the high routing capability of the build-up circuitries. The stiffener can provide a mechanical support for the metal slugs and the build-up circuitries. The placement location of the metal slugs can be accurately confined by the apertures of the stiffener or the stoppers to avoid the electrical connection failure between the metal slugs and the build-up circuitries resulted from the lateral displacement of the metal slugs, thereby improving the manufacturing yield greatly. The wiring board and the semiconductor assembly using the same are reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A wiring board with hybrid core, comprising:
a hybrid core that includes a stiffener and a plurality of metal slugs, wherein the stiffener has a plurality of apertures, and the metal slugs that extend into each of the apertures are coplanar with the stiffener;
a first build-up circuitry that covers the hybrid core in a first vertical direction and includes a first dielectric layer, first via openings, and a first conductive trace, wherein the first via openings in the first dielectric layer are aligned with the metal slugs, and the first conductive trace extends from the first dielectric layer in the first vertical direction and extends through the first via openings in the second vertical direction and directly contacts the metal slugs;
a second build-up circuitry that covers the hybrid core in a second vertical direction opposite the first vertical direction and includes a second dielectric layer, second via openings, and a second conductive trace, wherein the second via openings in the second dielectric layer are aligned with the metal slugs, and the second conductive trace extends from the second dielectric layer in the second vertical direction and extends through the second via openings in the first vertical direction and directly contacts the metal slugs; and
a plated through hole that extends through the stiffener of the hybrid core and provides an electrical connection between the first build-up circuitry and the second build-up circuitry.

2. The wiring board with hybrid core of claim 1, wherein the stiffener of the hybrid core includes resin laminate or ceramic.

3. The wiring board with hybrid core of claim 1, wherein the apertures of the stiffener are in close proximity to and laterally aligned with peripheral edges of the metal slugs in the lateral directions orthogonal to the vertical directions.

4. The wiring board with hybrid core of claim 1, further comprising an adhesive that contacts and is sandwiched between the metal slugs and the first build-up circuitry and between the stiffener and the first build-up circuitry.

5. The wiring board with hybrid core of claim 4, further comprising stoppers that serve as a placement guide for the metal slugs and are in close proximity to and laterally aligned with the metal slugs and laterally extend within peripheral edges of the apertures of the stiffener in lateral directions orthogonal to the vertical directions.

6. The wiring board with hybrid core of claim 1, wherein the metal slugs are substantially thicker than the conductive traces in the build-up circuitries and have a thickness range between 25 microns and 2 mm.
